(19) United States
(12) Patent Application Publication
(10) Pub. No.: US 2026/0331421 A1
(43) Pub. Date: Oct. 22, 2026

(54) SUBSTRATE PROCESSING APPARATUS

(71) Applicant: SAMSUNG ELECTRONICS CO., LTD., Suwon-si (KR)

(72) Inventors: HYUN-SIK HWANG, Suwon-si (KR); SUNGIL CHO, Suwon-si (KR); YOUNGHO KANG, Suwon-si (KR); TAEHWAN KANG, Suwon-si (KR); IN-JOONG KIM, Suwon-si (KR); SANGWON SON, Suwon-si (KR); SHINWOO HAN, Suwon-si (KR)

(73) Assignee: SAMSUNG ELECTRONICS CO., LTD., Suwon-si (KR)

(21) Appl. No.: 19/468,376

(22) Filed: Feb. 3, 2026

(30) Foreign Application Priority Data
Feb. 3, 2025 (KR) 10-2025-0012931

(51) Int. Cl. H01J 37/32

(52) U.S. Cl. CPC H01J 37/3211; H01J 37/32357; H01J 37/3244; H01J 2237/002; H01J 2237/3343

(57) ABSTRACT

Provided is a substrate processing apparatus including a process chamber, a gas injector connected to a ceiling portion of the process chamber, an induction coil on the process chamber, the induction coil being configured to form an electric field area in the process chamber, and a stage on a bottom portion of the process chamber, the stage being configured to receive a substrate, wherein a shape of the induction coil is changeable.

### CROSS-REFERENCE TO RELATED APPLICATIONS

This application claims priority to Korean Patent Application No. 10-2025-0012931 filed on Feb. 3, 2025, in the Korean Intellectual Property Office, the disclosure of which is incorporated by reference herein in its entirety.

### BACKGROUND

Embodiments of the present disclosure relate to a substrate processing apparatus.

Semiconductor devices may be manufactured using various semiconductor manufacturing processes. As one of the semiconductor manufacturing processes, an etching process of a semiconductor substrate may be performed. The etching process is a process of removing a portion of the semiconductor substrate or forming a desired pattern using a physical method and/or a chemical method. The etching process includes a wet etching process, a dry etching process, or an ion beam etching process.

As semiconductor devices are becoming highly integrated and made compact, a more precise etching method is required.

### SUMMARY

One or more embodiments provide a substrate processing apparatus for improving etching uniformity.

One or more embodiments also provide a substrate processing apparatus for improving etching precision.

According to an aspect of one or more embodiments, there is provided a substrate processing apparatus including a process chamber, a gas injector connected to a ceiling portion of the process chamber, an induction coil on the process chamber, the induction coil being configured to form an electric field area in the process chamber, and a stage on a bottom portion of the process chamber, the stage being configured to receive a substrate, wherein a shape of the induction coil is changeable.

According to another aspect of one or more embodiments, there is provided a substrate processing apparatus including a process chamber, a gas injector connected to a ceiling portion of the process chamber, an induction coil on the process chamber, the induction coil being configured to form an electric field area in the process chamber, a sub-gas injector connected to a wall portion of the process chamber, the sub-gas injector being configured to inject gas, and a stage on a bottom portion of the process chamber, the stage being configured to receive a substrate, wherein a shape of the induction coil is changeable, and wherein a distance between the ceiling portion of the process chamber and an effective lower end of the electric field area ranges from 4/15 to 7/15 of a distance between the ceiling portion of the process chamber and an upper surface of the stage.

According to still another aspect of one or more embodiments, there is provided a substrate processing apparatus including a process chamber, a stage on a bottom portion of the process chamber, the stage being configured to receive a substrate, and a plasma supply device on the process chamber, the plasma supply device being configured to supply plasma into the process chamber, wherein the plasma supply device includes a remote plasma chamber configured to generate the plasma, an induction coil configured to be on an outer surface of the remote plasma chamber, a housing connected to a lower end of the remote plasma chamber, the housing being configured to store the plasma generated from the remote plasma chamber, and a distribution plate connected to a lower end of the housing, the distribution plate including a plurality of distribution holes.

### BRIEF DESCRIPTION OF DRAWINGS

Embodiments will be more clearly understood from the following detailed description taken in conjunction with the accompanying drawings in which:

FIG. 1 is a sectional view of a substrate processing apparatus according to one or more embodiments;

FIG. 2 is a plan view of an induction coil according to one or more embodiments;

FIG. 3 is a sectional view of a substrate processing apparatus according to one or more embodiments;

FIG. 4 is a plan view of an induction coil according to one or more embodiments;

FIG. 5 is a sectional view of a substrate processing apparatus according to one or more embodiments;

FIG. 6 is a plan view illustrating a change in the shape of an induction coil according to one or more embodiments;

FIG. 7 is a sectional view of a substrate processing apparatus according to one or more embodiments;

FIG. 8 is a sectional view of a substrate processing apparatus according to one or more embodiments;

FIG. 9 is a rear view of a distribution plate according to one or more embodiments; and

FIG. 10 is a sectional view of a substrate processing apparatus according to one or more embodiments.

### DETAILED DESCRIPTION

Hereinafter, embodiments of the present disclosure will be described in more detail with reference to the accompanying drawings.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Also, the term “and/or” includes any and all combinations of one or more of the associated listed items. For example, an expression, “a and/or b” should be understood as including only a, only b and both a and b.

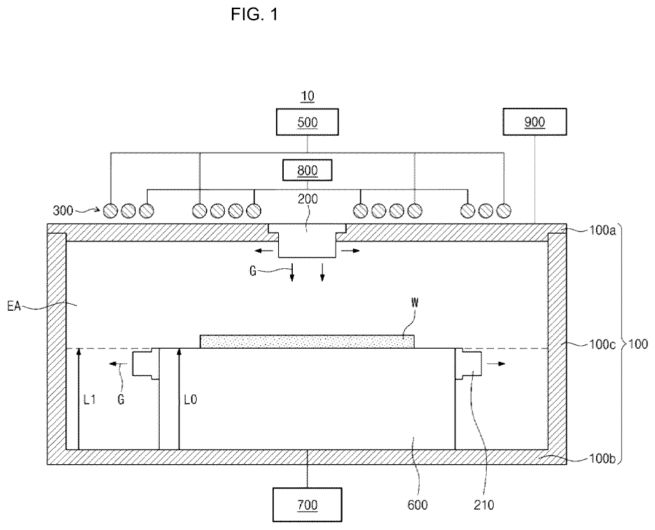

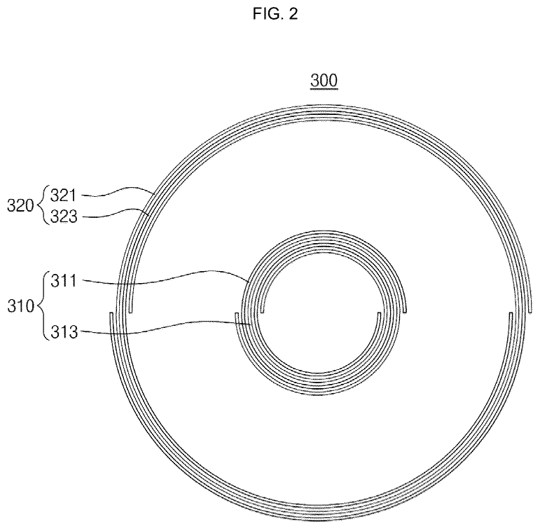

FIG. 1 is a sectional view of a substrate processing apparatus according to one or more embodiments. FIG. 2 is a plan view of an induction coil according to one or more embodiments.

Referring to FIGS. 1 and 2, the substrate processing apparatus 10 according to one or more embodiments may include a process chamber 100, a gas injector 200, the induction coil 300, a stage 600, and a power supply device 500.

More specifically, the substrate processing apparatus according to one or more embodiments may be etching equipment for performing an etching process on a substrate. For example, the substrate processing apparatus may be an inductively coupled plasma (ICP) etcher for performing a dry etching process on a substrate. For example, the substrate processing apparatus may be dry etching equipment that etches a substrate through plasma generated by injecting gas into an electric field formed by an induction coil. Here, the substrate may include a silicon on insulator (SOI) substrate, a metal substrate, a glass substrate, or a plastic substrate, as well as a semiconductor substrate made of a semiconductor material. The semiconductor substrate may be, for example, a silicon substrate, a germanium substrate, or a silicon-germanium substrate. Hereinafter, various embodiments of the substrate processing apparatus will be described.

The process chamber 100 may provide a process space of the substrate processing apparatus 10. Here, the process space may be an inner space of the process chamber 100. For example, a substrate processing process may be performed through the substrate processing apparatus 10 in the inner space of the process chamber 100. For example, the substrate processing apparatus 10 may perform a dry etching process in the inner space of the process chamber 100. The inner space may be separated from an external space by the process chamber 100. The process chamber 100 may have a cylindrical shape. However, embodiments are not limited thereto, and the process chamber 100 may be implemented in various shapes. The inner space of the process chamber 100 may be substantially a vacuum space. The inner space of the process chamber 100 may have, for example, a pressure of about 1×10⁻⁸ Torr to about 1×10⁻² Torr.

The process chamber 100 may include a ceiling portion 100a, a wall portion 100c extending downward from the edge of the ceiling portion 100a, and a bottom portion 100b provided on the lower end of the wall portion 100c. The inner space of the process chamber 100 may be a space surrounded by and/or adjacent to the ceiling portion 100a, the wall portion 100c, and the bottom portion 100b.

For example, the bottom portion 100b of the process chamber 100 may be a portion that covers and/or is provided on the lower surface in the inner space of the process chamber 100, and the wall portion 100c may be a portion that vertically extends from the edge of the bottom portion 100b and vertically surrounds the inner space of the process chamber 100. The ceiling portion 100a may be a portion that faces the bottom portion 100b of the process chamber 100 and covers the upper surface in the inner space of the process chamber 100.

The stage 600 may be provided in a lower space of the process chamber 100. For example, the stage 600 may be provided in a lower area of the inner space of the process chamber 100. For example, the stage 600 may be disposed on the bottom portion 100b of the process chamber 100.

The stage 600 may be configured to receive a substrate W. For example, the stage 600 may fix the substrate W while the process is performed. The stage 600 may have, for example, a cylindrical shape. For example, when compared to a planar area of the substrate W, the stage 600 may have a larger planar area sufficient to receive the substrate W.

In one or more embodiments, a circular hole may be defined in the center of the bottom portion 100b. For example, the bottom portion 100b may have a circular ring shape in a plan view that surrounds the circular hole. For example, gases in the process chamber 100 may be pumped out of the process chamber 100 through the circular hole.

In one or more embodiments, the stage 600 may include a chuck. The chuck may be provided at the top of the stage 600. The chuck may receive the substrate W. For example, the chuck may fix the substrate W while the process is performed. For example, the chuck may control the position of the substrate W while the process is performed. The chuck may have a circular plate shape. When compared to a planar area of the substrate W, the chuck may have a larger planar area sufficient to receive the substrate W.

In one or more embodiments, the chuck may be a vacuum chuck that includes a plurality of vacuum grooves and clamps the substrate W by vacuum. However, without being limited thereto, the chuck may include various types of chucks capable of positioning the substrate W, for example, an electrostatic chuck, a mechanical chuck, or a magnetic chuck.

In one or more embodiments, the stage 600 may include an edge ring. The edge ring may be provided along the side surface of the chuck. The edge ring may have a ring shape. For example, the edge ring may be provided in a ring shape along the periphery of the chuck. The edge ring may protect the edge of the substrate W. For example, the edge ring may control an electrical or thermal effect that may occur at the edge of the substrate W while the process is performed.

In one or more embodiments, the stage 600 may include a heat supply device. The heat supply device may control the temperature of the substrate W. For example, the heat supply device may maintain the substrate W at an optimal temperature for the etching process. For example, while the process is performed, the heat supply device may provide heat to the substrate W to assist in smoothly performing the process. The heat supply device may be provided inside the stage 600. The heat supply device may have a circular plate shape. However, embodiments are not limited thereto, and the heat supply device may be implemented in various shapes. The heat supply device may have, for example, a line shape extending in a certain pattern along the upper surface of the stage 600.

In one or more embodiments, a separate thermoelectric power supply device may be connected to the heat supply device. The thermoelectric power supply device may provide power to the heat supply device. The heat supply device may control the temperature of the substrate W using the power.

In one or more embodiments, a vacuum pump may be provided outside the process chamber 100. The vacuum pump may remove the gases in the process chamber 100 through a separate pipe connected to the process chamber 100 to maintain the inner space of the process chamber 100 in a high-vacuum state. The vacuum pump may lower the gas density in the process chamber 100 to improve the stability of plasma and the etch rate of the substrate W.

The gas injector 200 may be coupled to and/or connected to the ceiling portion 100a of the process chamber 100. For example, the gas injector 200 may be provided to penetrate the center of the ceiling portion 100a of the process chamber 100. The gas injector 200 may inject gas G into the inner space of the process chamber 100. Here, the gas G may be a gaseous material capable of etching the substrate W. The type of gas G may vary depending on an object to be etched, and the gas G may include, for example, CF₄, SF₆, C₂F₆, CHF₃, Cl₂, BCl₃, HBr, Ar, He, O₂, N₂, H₂, CO, or XeF₂ in a gaseous state, or a combination thereof.

The gas injector 200 may inject the gas G in various directions. For example, the gas injector 200 may inject the gas G downward from the ceiling portion 100a of the process chamber 100 toward the substrate W. For example, the gas injector 200 may radially inject the gas G from the ceiling portion 100a of the process chamber 100.

In one or more embodiments, a separate gas storage tank may be provided outside the process chamber 100. The gas storage tank may be connected to the gas injector 200 through a separate pipe. The gas storage tank may store the gas G that will be injected through the gas injector 200. For example, the gas storage tank may provide the gas G to the gas injector 200.

The induction coil 300 may be provided over the process chamber 100. The induction coil 300 may be provided outside the process chamber 100. For example, the induction coil 300 may be disposed over the ceiling portion 100a of the process chamber 100.

The induction coil 300 may receive an alternating current from the power supply device 500 and may induce a magnetic field. An induced electric field may be formed in the process chamber 100 through the induced magnetic field. Accordingly, the induction coil 300 may form an electric field area EA in the process chamber 100.

The substrate processing apparatus 10 according to one or more embodiments may form plasma capable of etching the substrate W, by injecting the gas G into the electric field area EA, which is formed from the induction coil 300, through the gas injector 200. Here, the plasma may include radicals and/or ions generated when the gas G is excited by the electric field.

As illustrated in FIG. 2, the induction coil 300 may include an inner coil 310 and an outer coil 320. The inner coil 310 may include a first inner coil 311 and a second inner coil 313, and the outer coil 320 may include a first outer coil 321 and a second outer coil 323.

For example, the inner coil 310 may have a spiral shape and may be disposed at the center of the induction coil 300, and the outer coil 320 may have a spiral shape with a diameter larger than a diameter of the inner coil 310, and may be disposed at the edge of the induction coil 300. For example, the outer coil 320 may surround and/or be adjacent to the inner coil 310.

The first inner coil 311 and the second inner coil 313 may be alternately disposed to form a spiral interdigital shape. The first outer coil 321 and the second outer coil 323 may be alternately disposed to form a spiral interdigital shape.

In one or more embodiments, the shape of the induction coil 300 is not limited to that illustrated in FIG. 2. The induction coil 300 illustrated in FIG. 2 is merely an example, and the substrate processing apparatus 10 may include induction coils 300 having various shapes. For example, the induction coil 300 may have a cylindrical shape, a circular ring shape, or a spring shape, in addition to the spiral shape.

The induction coil 300 may be formed of a conductive material. For example, the induction coil 300 may include copper (Cu), silver (Ag), aluminum (Al), gold (Au), a nickel-chromium alloy, stainless steel, molybdenum, tungsten (W), titanium (Ti), tantalum (Ta), or a combination thereof. However, the induction coil 300 may be formed of various materials, and the constituent material of the induction coil 300 is not limited thereto.

In one or more embodiments, the shape of the induction coil 300 may be changeable over time. For example, the induction coil 300 may be a shape-variable induction coil, the shape of which is changeable over time.

In one or more embodiments, the induction coil 300 may include a shape memory alloy. For example, the shape memory alloy may include nickel (Ni), titanium (Ti), copper (Cu), manganese (Mn), iron (Fe), zinc (Zn), aluminum (Al), hafnium (Hf), zirconium (Zr), chromium (Cr), silicon (Si), or a combination thereof. Since the induction coil 300 is formed of the shape memory alloy, the shape of the induction coil 300 may be changeable.

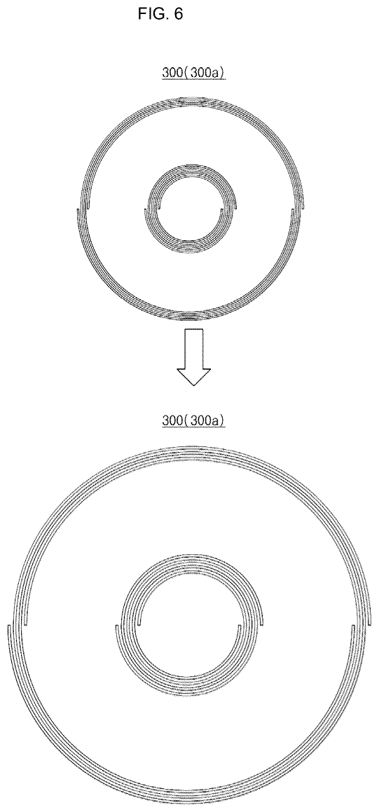

The substrate processing apparatus 10 according to one or more embodiments may control the strength and range of the induced magnetic field by changing the shape of the induction coil 300. Accordingly, the strength and range of the electric field area EA may be controlled. As a result, when the process is performed, the intensity and range of the plasma provided may be controlled for each area of the substrate W, and the etching uniformity and the etching precision of the substrate W may be improved. Specific details of the etching process depending on the change in the shape of the induction coil 300 will be described below with reference to FIG. 6.

The power supply device 500 may be connected to the induction coil 300. For example, the power supply device 500 may be connected to an end of the induction coil 300. The power supply device 500 may provide an alternating current (e.g., RF power) to the induction coil 300. For example, the induction coil 300 may induce a magnetic field using the alternating current provided by the power supply device 500 and may form the electric field area EA in the process chamber 100. The power supply device 500 may control the energy of the electric field area EA depending on the strength and frequency of the alternating current. The power supply device 500 may be, for example, an RF power supply device. The frequency of the power supply device 500 may be, for example, 13.56 Mhz.

In one or more embodiments, the substrate processing apparatus 10 may further include a shape control motor 800. The shape control motor 800 may be, for example, a stepper motor. The shape control motor 800 may be connected to an end of the induction coil 300. For example, the shape control motor 800 may be connected to some of the ends of the induction coil 300 to which the power supply device 500 is not connected. The shape control motor 800 may be disposed over the induction coil 300. For example, the shape control motor 800 may be disposed over the center of the induction coil 300.

The shape control motor 800 may change the shape of the induction coil 300. For example, the shape control motor 800 may wind the induction coil 300 to contract the induction coil 300.

In one or more embodiments, the substrate processing apparatus 10 may further include a cooler 900. The cooler 900 may be provided on one side of the induction coil 300. The cooler 900 may be provided, for example, above the induction coil 300. The cooler 900 may include a cooling fan and may operate the cooling fan to control the temperature of the induction coil 300. For example, the cooler 900 may rotate the cooling fan to remove heat of the induction coil 300, thereby cooling the induction coil 300. However, the configuration of the cooler 900 is not limited thereto, and the cooler 900 may be operated by natural convection or refrigerant circulation without the cooling fan.

In one or more embodiments, the substrate processing apparatus 10 may further include a bias controller 700. The bias controller 700 may be connected to the stage 600. For example, the bias controller 700 may be connected to the bottom or side of the stage 600 through separate wiring. The bias controller 700 may be electrically connected to the stage 600.

In one or more embodiments, the bias controller 700 may be configured to apply AC power to the stage 600. By applying the AC power, a negative bias voltage may be applied to the stage 600. For example, the bias controller 700 may use the AC power. When the process is performed, the bias controller 700 may improve the straightness of components of the plasma (e.g., ions in the plasma) descending toward the substrate W in the etching process of the substrate W by using the AC power. Accordingly, the bias controller 700 may improve the process performance capability of an etching process and/or a deposition process. In addition, the bias controller 700 may separately control the central portion and the edge portions of the substrate W. For example, different magnitudes of AC power may be applied to the central portion and the edge portion of the substrate W. Accordingly, the bias controller 700 may increase the uniformity of the etching process and/or the deposition process.

In one or more embodiments, when the stage 600 includes an electrostatic chuck, the substrate processing apparatus 10 may include a separate DC power supply device. The DC power supply device may be connected to the stage 600. The DC power supply device may provide separate DC power to the electrostatic chuck. Through the supply of the DC power, a DC bias voltage may be applied to the electrostatic chuck. The electrostatic chuck may fix the substrate W through the DC bias voltage.

In one or more embodiments, the substrate processing apparatus 10 may further include a sub-gas injector 210. The sub-gas injector 210 may be coupled to and/or connected to the outer surface of the stage 600. The sub-gas injector 210 may inject the gas G toward the wall portion 100c of the process chamber 100. The sub-gas injector 210 may inject additional gas G from around the substrate W in addition to the gas G injected into the process chamber 100 from the gas injector 200, thereby improving etching uniformity and etching precision.

In one or more embodiments, a plurality of sub-gas injectors 210 may be provided. For example, three sub-gas injectors 210 may be disposed along the periphery of the stage 600 in a plan view. For example, five to twelve sub-gas injectors 210 may be disposed along the periphery of the stage 600 in a plan view. For example, twelve to twenty sub-gas injectors 210 may be disposed along the periphery of the stage 600 in the plan view.

In one or more embodiments, the level L1 of an effective lower end of the electric field area EA may be substantially the same as the level L0 of the upper surface of the stage 600. Here, the effective lower end of the electric field area EA may indicate the lower end of an effective electric field area in which the electric field in the substrate processing apparatus 10 is capable of more effectively acting in the etching process. The effective electric field area may mean an area having energy greater than or equal to the minimum energy capable of making the gas G excited, among the areas formed by the electric field formed in the process chamber 100 by the induction coil 300 when the process is performed.

The substrate processing apparatus 10 according to one or more embodiments may be manufactured such that the vertical height of the process chamber 100 corresponds to the effective lower end of the electric field area EA. For example, the process chamber 100 of the substrate processing apparatus 10 may be provided such that the level L1 of the effective lower end of the electric field area EA is substantially the same as the level L0 of the upper surface of the stage 600.

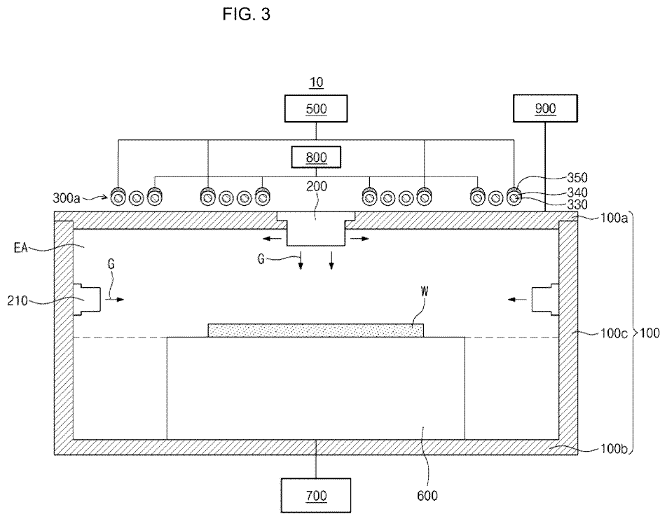

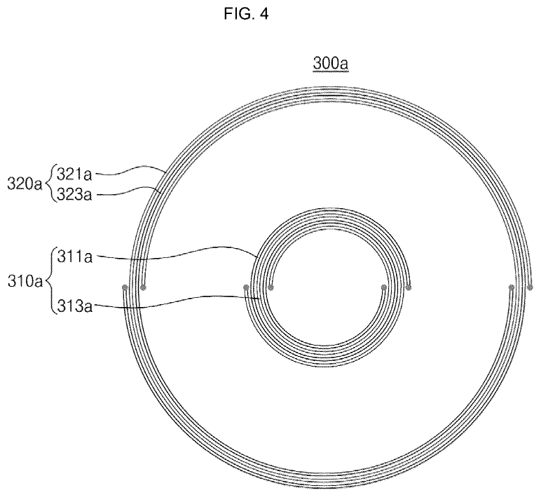

FIG. 3 is a sectional view of a substrate processing apparatus according to one or more embodiments. FIG. 4 is a plan view of an induction coil according to one or more embodiments. For convenience of description, the following description will be focused on differences from the above-described embodiment.

Referring to FIGS. 3 and 4, the induction coil 300a of the substrate processing apparatus 10a according to one or more embodiments may include a flexible insulating tube 340 and a liquid metal 330. The flexible insulating tube 340 may be physically contractible and expandable. For example, the flexible insulating tube 340 may be contracted and expanded by a shape control motor 800.

The flexible insulating tube 340 may form the exterior of the induction coil 300a. For example, the flexible insulating tube 340 may have a cylindrical shape that is open at an upper side and a lower side thereof. For example, the flexible insulating tube 340 may have a spiral coil shape. As illustrated in FIG. 4, the flexible insulating tube 340 may include an inner insulating tube 310a and an outer insulating tube 320a. The inner insulating tube 310a may include a first inner insulating tube 311a and a second inner insulating tube 313a, and the outer insulating tube 320a may include a first outer insulating tube 321a and a second outer insulating tube 323a.

For example, the inner insulating tube 310a may have a spiral shape and may be disposed at the center of the induction coil 300a, and the outer insulating tube 320a may have a spiral shape with a diameter larger than that of the inner insulating tube 310a and may be disposed at the edge of the induction coil 300a. For example, the outer insulating tube 320a may surround and/or be adjacent to the inner insulating tube 310a.

The flexible insulating tube 340 may be formed of an insulating material. The flexible insulating tube 340 may include, for example, polytetrafluoroethylene (PTFE), polyvinyl chloride (PVC), polyurethane resin (PUR), silicone rubber, polyethylene (PE), or a combination thereof.

The liquid metal 330 may be provided in the flexible insulating tube 340. For example, the liquid metal 330 fill the inner space of the flexible insulating tube 340. The liquid metal 330 may include a metallic material that exists in a liquid state at room temperature. Here, the room temperature may mean a temperature of 20 °C to 50 °C. For example, the liquid metal 330 may include mercury (Hg), gallium (Ga), indium (In), or a combination thereof. For example, the liquid metal 330 may include a gallium (Ga)-indium (In) alloy (EGaln).

In one or more embodiments, when the liquid metal 330 includes the gallium-indium alloy (EGaln), pretreatment using an acidic material may be performed on the inner surface of the flexible insulating tube 340. Here, the pretreatment may be performed by coating the inner surface of the flexible insulating tube 340 with the acid material. For example, the inner surface of the flexible insulating tube 340 may be coated with acid-treated siloxane oil. The electrical characteristics of the liquid metal 330 in the flexible insulating tube 340 may be improved through the pretreatment.

In one or more embodiments, the substrate processing apparatus 10a may further include a conductive polymer connection part 350. The conductive polymer connection part 350 may be connected to an end of the induction coil 300a. For example, the conductive polymer connection part 350 may coat an end of the flexible insulating tube 340 of the induction coil 300a.

For example, the conductive polymer connection part 350 may be provided at the ends of the induction coil 300a connected to a power supply device 500 and the ends of the induction coil 300a connected to the shape control motor 800. For example, the conductive polymer connection part 350 may be coated on the ends of the flexible insulating tube 340 to seal the liquid metal 330. The conductive polymer connection part 350 may prevent the liquid metal 330 from flowing out of the flexible insulating tube 340 and may improve the electrical conductivity of the induction coil 300a.

The conductive polymer connection part 350 may be formed of a conductive polymer material. The conductive polymer connection part 350 may include, for example, poly(3,4-ethylenedioxythiophene):poly(styrene sulfonate) (PEDOT:PSS).

In one or more embodiments, a sub-gas injector 210 may be coupled to and/or connected to a wall portion 100c of a process chamber 100. The sub-gas injector 210 may inject gas G toward the inside of the process chamber 100. The sub-gas injector 210 may penetrate the wall portion 100c of the process chamber 100. For example, the sub-gas injector 210 may be disposed on the wall portion 100c of the process chamber 100 so as to be located at a position spaced a distance of 4 cm to 7 cm apart from the upper surface of a substrate W. However, the position of the sub-gas injector 210 is not limited thereto, and the sub-gas injector 210 may be coupled to and/or connected to various locations of the process chamber 100.

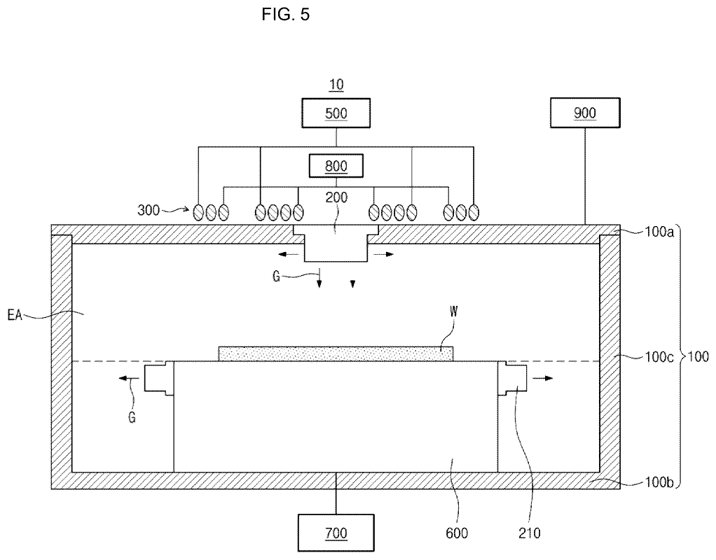

FIG. 5 is a sectional view of a substrate processing apparatus according to one or more embodiments. FIG. 6 is a plan view illustrating a change in the shape of an induction coil according to one or more embodiments. For convenience of description, the following description will be focused on differences from the above-described embodiments.

Referring to FIGS. 5 and 6, the substrate processing apparatus 10 or 10a may include the induction coil 300 or 300a, the shape of which is changeable over time. FIG. 5 is a sectional view illustrating the contraction of the induction coil 300 of the substrate processing apparatus 10 illustrated in FIG. 1. As illustrated in FIG. 5, the induction coil 300 may be contracted as the induction coil 300 is cooled through the cooler 900. In addition, the shape control motor 800 may wind the induction coil 300 by rotation, and the induction coil 300 may be contracted accordingly.

The induction coil 300 may be contracted in various forms. For example, the width of the induction coil 300 may be decreased as illustrated in FIGS. 5 and 6. However, the contraction shape of the induction coil 300 is not limited thereto and may vary depending on the shape of the induction coil 300.

As the induction coil 300 is contracted, the range of the electric field area EA formed from the induction coil 300 may be decreased. For example, the horizontal width and/or the vertical width of the electric field area EA may be decreased.

Thereafter, the induction coil 300 may generate heat by the alternating current supplied from the power supply device 500. Since the induction coil 300 is formed of a shape memory alloy that returns to its original shape when it reaches a specific temperature, the induction coil 300 may be expanded when the induction coil 300 reaches the specific temperature due to the heat. As a result, as illustrated in FIG. 6, the induction coil 300 may return to its original shape due to the heat.

As the induction coil 300 is expanded again, the range of the electric field area EA formed from the induction coil 300 may be increased. For example, the horizontal width and/or the vertical width of the electric field area EA may be increased.

When the induction coil 300a includes the flexible insulating tube 340 and the liquid metal 330 as illustrated in FIG. 4, the shape control motor 800 may wind the induction coil 300a through rotation to contract the induction coil 300a. As the induction coil 300a is contracted like the induction coil 300 illustrated in FIG. 5, the range of the electric field area EA formed from the induction coil 300a may be decreased.

Thereafter, the shape control motor 800 may rewind the induction coil 300a through reverse rotation to expand the induction coil 300a. As the induction coil 300a is expanded again as illustrated in FIG. 6, the range of the electric field area EA formed from the induction coil 300a may be increased.

As described above, the substrate processing apparatus 10 or 10a according to one or more embodiments may include the induction coil 300 or 300a capable of changing its shape, thereby adjusting the range of the electric field area EA. Accordingly, the substrate processing apparatus 10 or 10a may improve the etching uniformity and the etching precision of the substrate W in the process.

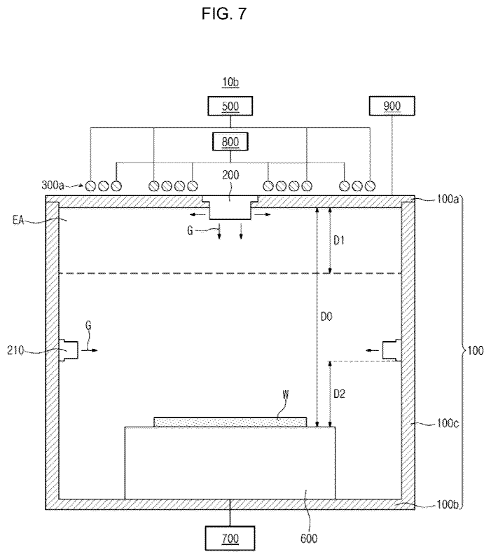

FIG. 7 is a sectional view of a substrate processing apparatus according to one or more embodiments. For convenience of description, the following description will be focused on differences from the above-described embodiments.

Referring to FIG. 7, a sub-gas injector 210 may be disposed between an effective lower end of an electric field area EA and a stage 600. For example, the sub-gas injector 210 may be disposed on a portion of a wall portion 100c of a process chamber 100 that is located at a level between the effective lower end and the upper surface of the stage 600.

For example, the vertical separation distance D2 between the sub-gas injector 210 and the upper surface of the stage 600 may range from ⅘ to 7/5 of the distance D1 between a ceiling portion 100a of the process chamber 100 and the effective lower end of the electric field area EA. In this case, the distance D1 between the ceiling portion 100a of the process chamber 100 and the effective lower end of the electric field area EA may range from 4/15 to 7/15 of the vertical separation distance D0 between the ceiling portion 100a of the process chamber 100 and the upper surface of the stage 600. For example, the vertical separation distance D0 between the ceiling portion 100a of the process chamber 100 and the upper surface of the stage 600 may be 15 cm. For example, the distance D1 between the ceiling portion 100a of the process chamber 100 and the effective lower end of the electric field area EA may range from 4 cm to 7 cm. For example, the vertical separation distance D2 between the sub-gas injector 210 and the upper surface of the stage 600 may range from 4 cm to 7 cm.

The substrate processing apparatus 10b according to one or more embodiments may include the sub-gas injector 210 disposed at the above-described position, thereby improving the uniformity of distribution of gas G provided to the electric field area EA. As a result, the substrate processing apparatus 10b may improve the etching uniformity and the etching precision of a substrate W in a process.

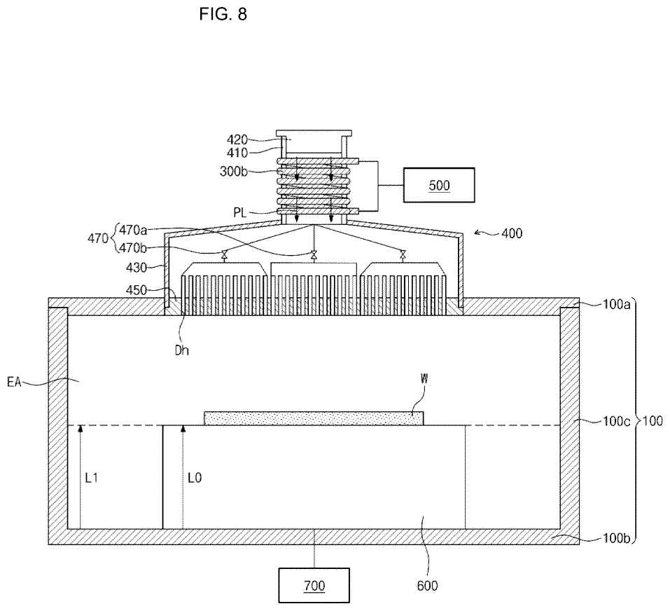

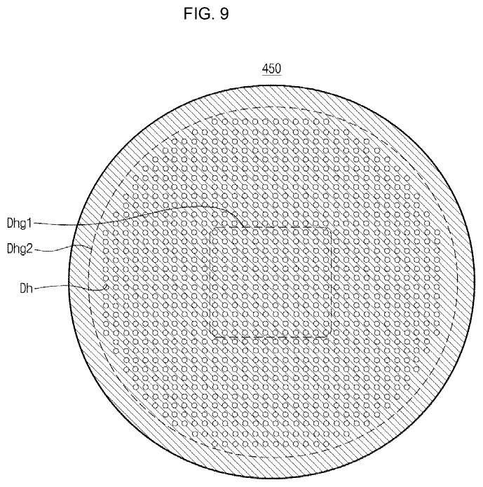

FIG. 8 is a sectional view of a substrate processing apparatus according to one or more embodiments. FIG. 9 is a rear view of a distribution plate according to one or more embodiments. For convenience of description, the following description will be focused on differences from the above-described embodiments.

Referring to FIGS. 8 and 9, the substrate processing apparatus 10c according to one or more embodiments may include a plasma supply device 400. The plasma supply device 400 may be provided on a process chamber 100. The plasma supply device 400 may be coupled to and/or connected to a ceiling portion 100a of the process chamber 100. For example, the plasma supply device 400 may penetrate the ceiling portion 100a of the process chamber 100.

The plasma supply device 400 may supply plasma PL into the process chamber 100. In addition, the plasma supply device 400 may control the supply flow rate of the plasma PL supplied into the process chamber 100. Accordingly, the plasma supply device 400 may control the etching uniformity and the etching precision of a substrate W when a process is performed.

The plasma supply device 400 may include a remote plasma chamber 410, a gas injector 200, an induction coil 300b, a housing 430, and the distribution plate 450.

The remote plasma chamber 410 may provide a space in which the plasma PL is generated. The plasma PL may be generated in the remote plasma chamber 410. The remote plasma chamber 410 may be provided over the process chamber 100. For example, the remote plasma chamber 410 may be disposed at a position away from the process chamber 100 and may separately provide a space in which the plasma PL is generated.

The remote plasma chamber 410 may have a cylindrical shape smaller than a shape of the process chamber 100. For example, the remote plasma chamber 410 may have a cylindrical shape that is open at an upper side and a lower side thereof.

The gas injector 200 may be coupled to and/or connected to an upper portion of the remote plasma chamber 410. For example, the gas injector 200 may be coupled to and/or connected to the open upper side of the remote plasma chamber 410. The gas injector 200 may inject the gas G (refer to FIG. 1) into the remote plasma chamber 410. The gas injector 200 may be connected to a separate gas storage tank and may receive the gas G (refer to FIG. 1) from the gas storage tank.

The induction coil 300b may be provided on the outer surface of the remote plasma chamber 410. The induction coil 300b may surround and/or be adjacent to the outer surface of the remote plasma chamber 410. The induction coil 300b may generate an electric field in the remote plasma chamber 410. The gas G (refer to FIG. 1) injected from the gas injector 200 may be changed into the plasma PL by the electric field generated by the induction coil 300b. In other words, the plasma PL may be generated in the remote plasma chamber 410 by the gas injector 200 and the induction coil 300b.

The housing 430 may be coupled to and/or connected to the lower end of the remote plasma chamber 410. For example, the remote plasma chamber 410 may be coupled to and/or connected to the upper end of the housing 430. For example, the remote plasma chamber 410 may penetrate the upper end of the housing 430.

The housing 430 may store the plasma PL generated from the remote plasma chamber 410. For example, the housing 430 may store the plasma PL introduced into the housing 430 from the lower end of the remote plasma chamber 410.

The distribution plate 450 may be coupled to and/or connected to the lower end of the housing 430. The distribution plate 450 may have a plurality of distribution holes Dh defined therein. For example, the distribution plate 450 may have a showerhead shape including the distribution holes Dh.

The distribution holes Dh may be spaces through which the plasma PL stored in the housing 430 passes to face toward the inside of the process chamber 100 when an etching process is performed. For example, the distribution holes Dh may guide the progression path of the plasma PL.

The distribution holes Dh may penetrate the distribution plate 450. For example, the distribution holes Dh may penetrate the upper and lower surfaces of the distribution plate 450 in the vertical direction. As illustrated in FIG. 9, the distribution holes Dh may have a circular shape in a plan view. However, the shape of the distribution holes Dh is not limited thereto, and the distribution holes Dh may have, for example, a polygonal shape. In addition, the number of distribution holes Dh is not limited to that illustrated in FIG. 9, and various numbers of distribution holes Dh may be defined in the distribution plate 450.

In one or more embodiments, the plasma supply device 400 may further include plasma supply valves 470. The plasma supply valves 470 may be provided in the housing 430. The plasma supply valves 470 may be connected between the remote plasma chamber 410 and the distribution holes Dh.

For example, the plasma supply valves 470 may be connected to the distribution holes Dh through separate pipes, respectively, and may control the amount of the plasma PL introduced into the distribution holes Dh from the remote plasma chamber 410. In this case, the plasma supply valves 470 may individually control the flow rate of the plasma PL. Accordingly, the plasma supply device 400 may improve the etching uniformity and the etching precision of the substrate W in the etching process.

In one or more embodiments, the plasma supply valves 470 may include a first plasma supply valve 470a and a second plasma supply valve 470b. In this case, the first plasma supply valve 470a and the second plasma supply valve 470b may be connected to different distribution holes Dh. For example, the plasma supply valves 470 may control the flow rate of the plasma PL for each area of the distribution plate 450.

In one or more embodiments, some of the distribution holes Dh of the distribution plate 450 may form a first distribution hole group Dhg1, and the others may form a second distribution hole group Dhg2. For example, as illustrated in FIG. 9, among the distribution holes Dh, the distribution holes Dh in the central portion of the distribution plate 450 may form the first distribution hole group Dhg1, and the distribution holes Dh in the edge portion of the distribution plate 450 other than the central portion may form the second distribution hole group Dhg2.

In this case, the first plasma supply valve 470a may be connected to the distribution holes Dh corresponding to the first distribution hole group Dhg1, and the second plasma supply valve 470b may be connected to the distribution holes Dh corresponding to the second distribution hole group Dhg2. Accordingly, the first plasma supply valve 470a may control the amount of the plasma PL supplied through the first distribution hole group Dhg1, and the second plasma supply valve 470b may control the amount of the plasma PL supplied through the second distribution hole group Dhg2.

In one or more embodiments, the distribution plate 450 may include distribution hole groups corresponding to various numbers of distribution holes Dh and various areas of distribution holes Dh. In this case, the distribution hole groups may be connected to different plasma supply valves 470, respectively. For example, each of the plasma supply valves 470 may control the amount of the plasma PL in various forms by varying the number of distribution holes Dh being controlled and the area of the distribution holes Dh being controlled.

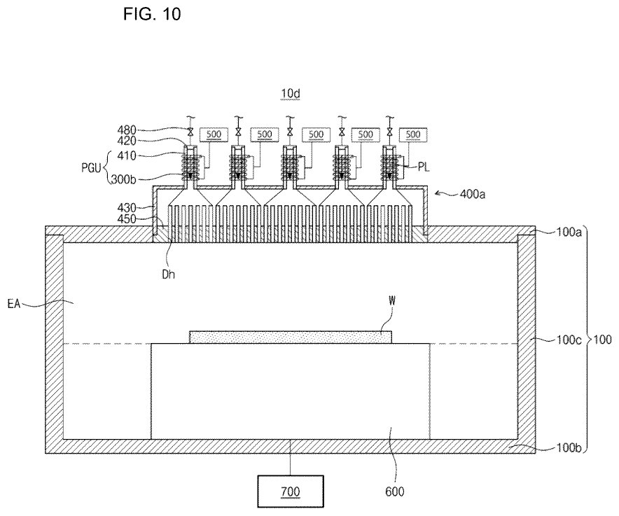

FIG. 10 is a sectional view of a substrate processing apparatus according to one or more embodiments. For convenience of description, the following description will be focused on differences from the above-described embodiments.

Referring to FIG. 10, an induction coil 300 and a remote plasma chamber 410 may form a plasma generation unit PGU, and a plurality of plasma generation units PGU may be provided.

For example, plasma PL provided into a process chamber 100 may be generated by the plurality of plasma generation units PGU. For example, as illustrated in FIG. 10, the substrate processing apparatus 10d may include five or more plasma generation units PGU.

Each of the plasma generation units PGU may be connected to distribution holes Dh through a separate pipe. The plasma generation unit PGU may control the amount of the plasma PL injected into the process chamber 100 through the connected distribution holes Dh. The number of distribution holes Dh connected to each of the plasma generation units PGU is not limited to that illustrated in FIG. 10. Each of the plasma generation units PGU may control the amount of the plasma PL in various forms by varying the number of distribution holes Dh being controlled and the area of the distribution holes Dh being controlled.

In one or more embodiments, the substrate processing apparatus 10d may further include gas supply valves 480. The gas supply valves 480 may be connected to the plasma generation units PGU, respectively. The gas supply valves 480 may be connected to gas injectors 200, respectively. For example, the gas supply valves 480 may control the amounts of gas G injected into the remote plasma chambers 410 through the gas injectors 200. Accordingly, the gas supply valves 480 may control the generation flow rates of the plasma PL of the plasma generation units PGU.

By connecting the plurality of plasma generation units PGU to the distribution holes Dh and connecting the gas supply valves 480 to the plasma generation units PGU, the substrate processing apparatus 10d according to one or more embodiments may control the flow rate of the plasma PL injected into the process chamber 100 for each area of a distribution plate 450.

As a result, the plasma generation units PGU and the gas supply valves 480 may improve the etching uniformity and the etching precision of a substrate W in an etching process.

The substrate processing apparatuses according to the embodiments of the present disclosure may improve etching uniformity.

The substrate processing apparatuses according to the embodiments of the present disclosure may improve etching precision.

While embodiments have been described with reference to the figures, it will be understood by those of ordinary skill in the art that various changes in form and details may be made therein without departing from the spirit and scope as defined by the following claims and their equivalents.

What is claimed is:

1. A substrate processing apparatus comprising:
a process chamber;
a gas injector connected to a ceiling portion of the process chamber;
an induction coil on the process chamber, the induction coil being configured to form an electric field area in the process chamber; and
a stage on a bottom portion of the process chamber, the stage being configured to receive a substrate,
wherein a shape of the induction coil is changeable.

2. The substrate processing apparatus of claim 1, further comprising:
a sub-gas injector connected to an outer surface of the stage and configured to inject gas toward a wall portion of the process chamber.

3. The substrate processing apparatus of claim 1, further comprising:
a sub-gas injector connected to a wall portion of the process chamber and configured to inject gas.

4. The substrate processing apparatus of claim 1, wherein a level of an effective lower end of the electric field area is set to be the same as a level of an upper surface of the stage.

5. The substrate processing apparatus of claim 1, further comprising:
a shape control motor connected to an end of the induction coil and configured to wind the induction coil to change the shape of the induction coil.

6. The substrate processing apparatus of claim 1, wherein the induction coil comprises a shape memory alloy.

7. The substrate processing apparatus of claim 6, further comprising:
a cooler on one side of the induction coil, the cooler being configured to cool the induction coil.

8. The substrate processing apparatus of claim 7, further comprising:
a power supply device connected to the induction coil and configured to supply an alternating current to the induction coil.

9. The substrate processing apparatus of claim 8, wherein the induction coil is configured to contract based on the induction coil being cooled through the cooler, and
wherein the induction coil is configured to be expanded by heat generated by resistance of the induction coil and the alternating current.

10. The substrate processing apparatus of claim 1, wherein the induction coil comprises a flexible insulating tube and a liquid metal in the flexible insulating tube.

11. The substrate processing apparatus of claim 10, wherein the flexible insulating tube comprises polytetrafluoroethylene (PTFE), polyvinyl chloride (PVC), polyurethane resin (PUR), silicone rubber, polyethylene (PE), or a combination thereof, and
wherein the liquid metal comprises mercury (Hg), gallium (Ga), indium (In), or a combination thereof.

12. The substrate processing apparatus of claim 10, further comprising:
a conductive polymer connection part connected to an end of the induction coil.

13. The substrate processing apparatus of claim 10, further comprising:
a shape control motor connected to an end of the induction coil,
wherein the shape control motor is configured to wind the induction coil to contract the induction coil, and
wherein the shape control motor is further configured to rewind the induction coil to expand the induction coil.

14. A substrate processing apparatus comprising:
a process chamber;
a gas injector connected to a ceiling portion of the process chamber;
an induction coil on the process chamber, the induction coil being configured to form an electric field area in the process chamber;
a sub-gas injector connected to a wall portion of the process chamber and configured to inject gas; and
a stage on a bottom portion of the process chamber, the stage being configured to receive a substrate,
wherein a shape of the induction coil is changeable, and
wherein a distance between the ceiling portion of the process chamber and an effective lower end of the electric field area ranges from 4/15 to 7/15 of a distance between the ceiling portion of the process chamber and an upper surface of the stage.

15. The substrate processing apparatus of claim 14, wherein a distance between the sub-gas injector and the upper surface of the stage ranges from ⅘ to 7/5 of the distance between the ceiling portion of the process chamber and the effective lower end of the electric field area.

16. A substrate processing apparatus comprising:
a process chamber;
a stage on a bottom portion of the process chamber, the stage being configured to receive a substrate; and
a plasma supply device on the process chamber, the plasma supply device being configured to supply plasma into the process chamber,
wherein the plasma supply device comprises:
a remote plasma chamber configured to generate the plasma;
an induction coil configured to be on an outer surface of the remote plasma chamber;
a housing connected to a lower end of the remote plasma chamber and configured to store the plasma generated from the remote plasma chamber; and
a distribution plate connected to a lower end of the housing, the distribution plate comprising a plurality of distribution holes.

17. The substrate processing apparatus of claim 16, further comprising:
plasma supply valves in the housing.

18. The substrate processing apparatus of claim 17, wherein the plasma supply valves comprise a first plasma supply valve and a second plasma supply valve,
wherein some of the plurality of distribution holes of the distribution plate form a first distribution hole group,
wherein others of the plurality of distribution holes of the distribution plate form a second distribution hole group,
wherein the first plasma supply valve is configured to control an amount of the plasma supplied through the first distribution hole group, and
wherein the second plasma supply valve is configured to control an amount of the plasma supplied through the second distribution hole group.

19. The substrate processing apparatus of claim 16, wherein the induction coil and the remote plasma chamber form a plasma generation unit,
wherein the plasma generation unit comprises a plurality of plasma generation units, and
wherein the substrate processing apparatus further comprises gas supply valves connected to the plurality of plasma generation units, respectively.

20. The substrate processing apparatus of claim 16, further comprising:
a bias controller connected to the stage and configured to control a direction of progression of the plasma.
